(19) United States
(12) Patent Application Publication
(10) Pub. No.: US 2011/0117514 A1
(43) Pub. Date: May 19, 2011

(54) Silicon Firnaceware for Stressed Film

(75) Inventors: Sang In Lee, Sunnyvale, CA (US); Fergal John O'Moore, Los Gatos, CA (US); Karl Anthony Williams, Scotts Valley, CA (US)

(73) Assignee: Fergal John O'Moroe, Sunnyvale, CA (US)

(21) Appl. No.: 12/618,566

(22) Filed: Nov. 13, 2009

(51) Int. Cl. H01L 21/683; C23C 14/48; B32B 9/00

(52) U.S. Cl. 432/253; 427/527; 428/446; 257/E21.001

(57) ABSTRACT

A method of fabricating the semiconductor wafer processing fixtures for having longer longevity on high stressed film applications such as LPCVD-SiN, silicon carbide and other ceramics than that of non-processed parts. One aspect of the invention includes nitriding, oxidizing, or carbiding a surface layer of a polysilicon part, such as furnaceware, for converting silicon to a silicon compound and its converted surface covers and masks the underlying polycrystalline structure. A plasma immersion ion implantation of a heavy noble gas or carbon, silicon or nitrogen is followed by to form high-energy states creating gettering states adjacent the surface and the ion implanted region serves to anchor production layers such as LPCVD-SiN forming on the polysilicon part. As a result of gettering effect, tightly bonded high stressed film onto a polysilicon part allows the CVD deposition of much thicker films without peeling or cracking as long as the gettering effect remains.

### FIELD OF THE INVENTION

This invention references previously filed provisional applications 61/145,514, filed Nov. 14, 2008.

This invention relates generally to furnaceware used in the thermal treatment of semiconductor wafers. In particular, the invention relates to pre-treatment of the surface of silicon furnaceware.

### BACKGROUND ART

Batch thermal processing of silicon wafers is used for several purposes including the thermal chemical deposition (CVD) of silicon nitride (nitride) layers and other materials including silicon oxide (oxide) and polysilicon. Other types of batch processing may benefit from the invention described below. The typical commercial arrangement includes an oven, a tower placed within the oven on top of a pedestal for supporting plural silicon wafers in a vertical stack, and a liner separating the tower from walls of the oven. Often gas injectors are placed between the tower and the liner to inject gas at chosen vertical positions. Until recently, the tower, tower pedestal, liner, and injectors were composed of fused quartz. However, with decreasing feature sizes, quartz is felt to produce too many particles which fall on the wafers and drastically reduce yield. Silicon carbide towers have been suggested as a replacement for quartz towers, but silicon carbide presents its own problems.

More recently, silicon furnaceware has been introduced by Integrated Materials, Inc. of Sunnyvale, Calif. See for example, U.S. Pat. No. 6,455,395 and application publication 2008/0152805, both to Boyle et al. The preferred silicon material is virgin polysilicon, which is grown as an ingot by chemical vapor deposition using different types of silane as the precursor. Virgin poly is very pure. It forms as polycrystalline material. The latter also discloses polysilicon dummy and baffle wafers to occupy empty and buffer positions in the tower. Reynolds et al. describe in US patent application publication 2007/0169701 both prior and new methods of forming the tubular liner from staves of virgin polysilicon.

Especially for nitride CVD applications, suggestions have been made to pre-coat the silicon tower with a silicon nitride layer before its use in depositing nitride on commercial wafers in order to anchor subsequent nitride layers formed in commercial operation. See, for example, US patent application publication 2002/0170487 to Zehavi et al. The nitride to pre-coating is easily practiced since an oven similar to that used for commercial CVD can also be used for the nitride pre-coat.

The nitride pre-coat, however, has not routinely been successful. Often, after relatively few production cycles, the thickening nitride tends to generate particles. Even if the tower and other furnaceware are refurbished by being stripped and again pre-coated, the refurbishment is not completely successful and the expensive furnaceware needs to be replaced. None of the currently available material choices or surface finishes enables an acceptable amount of cumulative deposition before the deposited film begins to shed particles, delaminate, or crack.

### SUMMARY OF THE INVENTION

One aspect of the invention includes nitriding, oxidizing, or carbiding a surface layer of a polysilicon part, particularly one used in a semiconductor processing chamber, such as furnaceware. The nitriding and oxidizing may be done in a process for converting silicon to a silicon compound with a nitrogen-containing or oxygen-containing gas, either in a thermal process or in a plasma process. The nitriding, oxidizing, or carbiding can be performed by implanting nitrogen, oxygen, or carbon into the surface. Advantageously, the converted surface, which may be amorphous, covers and masks the underlying polycrystalline structure.

In another aspect of the invention, a polysilicon part is ion implanted with a heavier noble gas or carbon, silicon or nitrogen to form high-energy states adjacent the surface. Of itself, the ion implanted region serves to anchor production layers forming on the polysilicon part. The implantation may be combined with the nitriding or oxidizing conversion process performed with before or after the conversion.

In yet another aspect of the invention, ion implantation is used to disorder the silicon surface, preferably turning the polysilicon to amorphous silicon or to create high-energy states within the polysilicon, which act as gettering sites.

### BRIEF DESCRIPTION OF THE DRAWINGS

The above ad other objects, features, and advantages of the present invention will be better understood from the following description taken in conjunction with the accompanying drawings, in which

FIG. 1 is the cross-sectional view of silicon furnaceware which has cracking and peeling of the high stress film

FIG. 2 is the cross-sectional view of silicon furnaceware which was roughened and having a native oxide

FIG. 3 is the cross-sectional view of silicon furnaceware which was passivated with hydrogen atoms by a HF cleaning process.

FIG. 4 is the cross-sectional view of silicon furnaceware which is covered with a thermally grown amorphous silicon-nitride or silicon-oxide layer having chemical affinity with silicon.

FIG. 5 is the cross-sectional view of silicon furnaceware processed with a plasma immersion ion implantation (PIII) with atoms having smaller or equal covalent radius than silicon or inert gas to provide the region of high density of defects.

FIG. 6 is the cross-sectional view of silicon furnaceware which has cleaned with SC1/SC2 cleaning processes to remove contaminants and particles and keep hydrophilic surface.

FIG. 7 is the cross-sectional view of silicon furnaceware having the high-stress region near or buried beneath the surface of the silicon body

FIG. 8 is the cross-sectional view of PIII processed silicon furnaceware having nitrided or oxidized surface

FIG. 9 is the graph shows the gettering oxygen atoms from the surface oxide layer to the Pill region of high stress, higher doses of 5×10¹⁴/cm² and greater.

FIG. 10 is the cross-sectional view of silicon furnaceware that Pill process and nitridation combined in a single process.

FIG. 11 is the graph shows the depth profile of nitrogen concentration of silicon furnaceware processed with PIII.

FIG. 12 is the diagram of the PIII system shows a silicon tower under PIII processing.

FIG. 13 is the results of LPCVD SiN film particle performance to compare the longevity with, without PIII, and with a combination of an amorphous layer on a silicon tower.

### DETAILED DESCRIPTION OF THE PREFERRED EMBODIMENTS

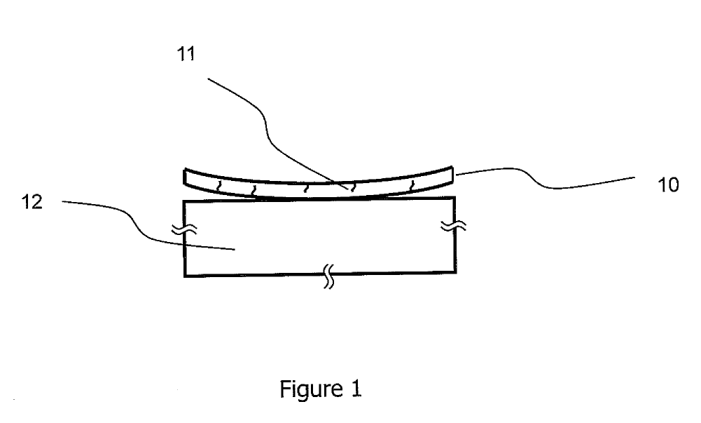

Although we are not bound by our understanding of the invention, we believe the nitride pre-coat suffers from several factors. The nitride pre-coat is a separate layer 10, illustrated in the cross-sectional view of FIG. 1, that is coated on the underlying polycrystalline body 12 and forms with its own crystallography although there may be some crystallographic templating from the surface on which it is deposited. The interface between the silicon furnaceware and the nitride pre-coat is very sharp. The nitride tends to deposit with significant tensile stress, which reduces the bonding strength to the polycrystalline silicon. The differential coefficients of thermal expansion (CTE) between the nitride film and polysilicon in combination with the tensile stress also promote cracking 11 and peeling of the thick stressed film 10.

In a first aspect of the invention, the silicon surface of the furnaceware is converted to a compound which is preferably amorphous and strongly binds to the underlying unconverted silicon. Examples of the converted materials are silicon nitride, silicon oxide, silicon oxynitride, and silicon carbide. Silicon nitride is of particularly interest in forming a strongly bonded silicon nitride surface on the wafer tower or other chamber part used in the deposition of silicon nitride by low pressure chemical vapor deposition (LPCVD) in forming integrated circuits. The conversion may be performed by nitriding a surface layer of the silicon furnaceware to convert it to silicon nitride in the presence of a nitrogen-containing gas. As a result, unlike deposited layers of silicon nitride, there is no distinct interface between the silicon body and the nitride film, the two surfaces are intermixed and merge, and the nitrided film strongly bonds to the underlying silicon body.

An example of a process for surface treating a silicon part for use in semiconductor process, such as a silicon tower, may be performed after the silicon parts have been machined and, if necessary, assembled into their final form. In one exemplary process for silicon towers, liners, and injectors, a virgin polysilicon ingot is sliced into smaller members, which are machined into their final form. The parts are degreased, cleaned, and then subjected to bead blasting to roughen the surface followed by an etch to relieve the strain. The silicon parts, including perhaps some parts not composed of virgin poly, such as the large tower bases, may be assembled and fused together with an adhesive composed of spin-on glass and silicon powder as described by Boyle et al. in U.S. Pat. No. 7,083,694. The parts and adhesive are fused by firing at high temperatures of about 1,000° C. in air or controlled atmosphere for several hours. The preparation of polysilicon baffle wafers, preferably formed from randomly oriented Czochralski silicon, dispenses with any assembly or fusing. The parts are then cleaned and would otherwise be ready for use except for the surface conversion or modification of the invention.

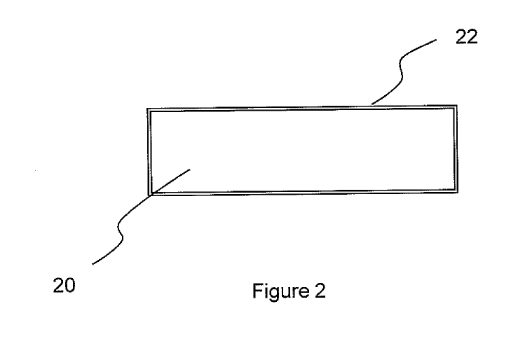

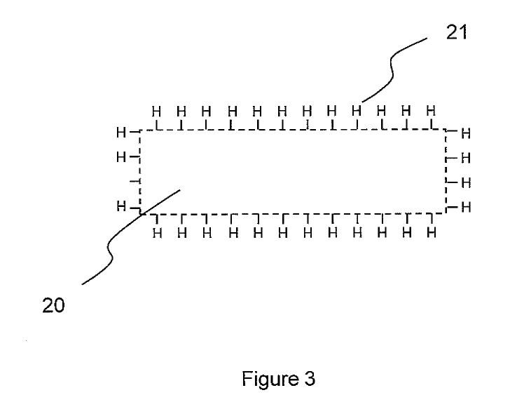

An example of the surface treatment process begins with a silicon body 20, such as an assembled tower or a simple dummy wafer, shown in the cross-sectional view of FIG. 2. The silicon body is composed of polysilicon with distinct crystallites and grain boundaries therebetween and typically has a roughened surface covered with a native oxide layer 22. The native oxide layer 22 is removed by a hydrofluoric acid (I-IF) etch, and the surface is then subjected to a hydrogen treatment in an ambient of hydrogen (H₂) to passivate the surface with hydrogen atoms 21, as shown in the cross-sectional view of FIG. 3.

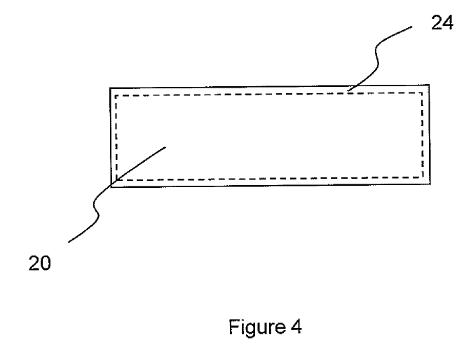

The silicon body 20 is then thermally nitrided to form, as shown in the cross-sectional view of FIG. 4, a thermally grown amorphous layer 24 of silicon nitride having chemical affinity with the underlying silicon. The thermal nitridation can be performed in an oven held at greater than 900° C. in an ambient of a nitrogen-containing gas, such as ammonia (NH₃). The amorphous SiN layer 24 converts the surface of the polysilicon into generally amorphous and uniform silicon nitride and thus suppresses the polysilicon grain boundaries near the surface. The reactive conversion process, which tends to produce uniform amorphous silicon nitride, differs from CVD deposition using gaseous silicon and nitrogen precursors. In the latter process, the CVD nitride films tend to nucleate on the underlying silicon polycrystallites and follow their morphology. Nitriding does not involve the substantial use of gaseous silicon precursors. Instead, the silicon body provides the silicon component in solid reactive form. Similarly, the later described oxidation process involves no substantial gaseous silicon precursors.

Incorporating nitrogen into the surface of polysilicon pails forms silicon nitride (SiNₓ). The converted silicon nitride may be an amorphous layer, which may be thinner than 10 nm, and be integral to the underlying silicon material rather than a separate coating distinct from the underlying silicon part. It is believed that the amorphous nitride layer blends gradually into the underlying silicon with no distinct atomic-scale boundary. By creating a silicon nitride surface, the CTE of the surface of the treated silicon furnaceware is more closely match to the CTE of the silicon nitride being CVD deposited on the wafers during production and hence the furnaceware during the CVD process, thereby more closely matching expansions during thermal cycling. The silicon nitride surface of the nitrided polysilicon silicon part allows a better chemical bond, specifically a covalent bond, to be created between the silicon nitride surface and the silicon nitride layers being CVD deposited. The covalent bonding between the nitrided layer and the underlying silicon body is almost impossible to break. The nitrogen incorporation also creates a diffusion barrier, an effect expected to be useful in blocking the potential diffusion of materials such as hydrogen or phosphorus, which could attack and weaken the polysilicon. Silicon nitride is also expected to be a stronger material than polysilicon to thus increase the overall strength of the part by repairing the surface, creating an amorphous layer, and filling in the triple point junction of the polysilicon grain boundaries.

Such a tightly bonded amorphous silicon nitride film 24 allows the CVD deposition of much thicker nitride films without peeling or cracking.

Alternatively to nitridation, the silicon part can be oxidized. For example, a thermal wet oxidation at greater than 900° C. in an ambient of hydrogen and oxygen gases (H₂/O₂) produces a thin amorphous silicon dioxide (SiO₂) surface overlying, masking, and linking the underlying polycrystalline silicon body. The oxidized furnaceware is particularly useful for thermal CVD, oxidation, or annealing of oxide layers but may also be used for other thermal applications. It is also possible to convert the silicon surface to silicon oxynitride (SiON).

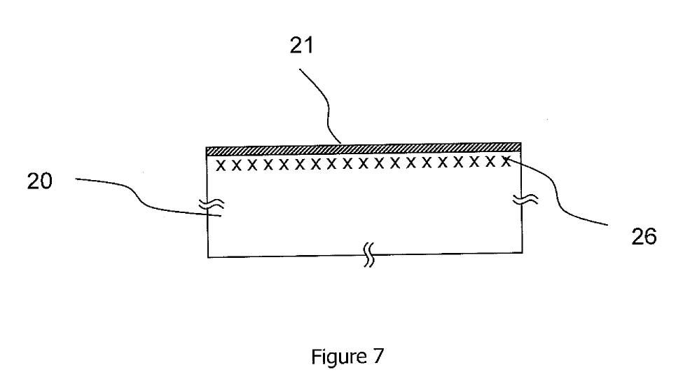

According to another aspect of the invention, after nitridation or oxidation, the silicon body 20 is ion implanted, as shown in the cross-sectional view of FIG. 7, to form regions 26 of high density of defects with high energy state generally underlying or at the bottom interface with the nitrided layer 24, for example, at depths of the implanted ions preferably in the range of 1 to 50 nm. In this embodiment of the invention, the ion implantation follows the nitridation or oxidation. The ion species is preferably chosen to have a covalent radius that is smaller than or equal to that of silicon, for example in the case of a nitrided surface, carbon (C), nitrogen from nitrogen gas (N₂), or silicon (Si), or alternatively to be an inert gas such as neon (Ne), argon (Ar), krypton (Kr), or xenon (Xe). Carbon, nitrogen, oxygen, and silicon are among the few reactive elements that do not introduce problems in semiconductor processing. Values of the covalent radius for different atoms are listed in TABLE 1.

TABLE 1

| | Covalent |
|---|---|
| | Radius |
| Element | (nm) |
| Si | 0.111 |
| Ar | 0.097 |
| N | 0.075 |
| O | 0.073 |
| Ne | 0.069 |
| Kr | 0.11 |
| Xe | 0.13 |

The ion implantation is preferably performed with ions of greater than 1 keV implanting a dose of greater than 10¹⁴ atoms/cm².

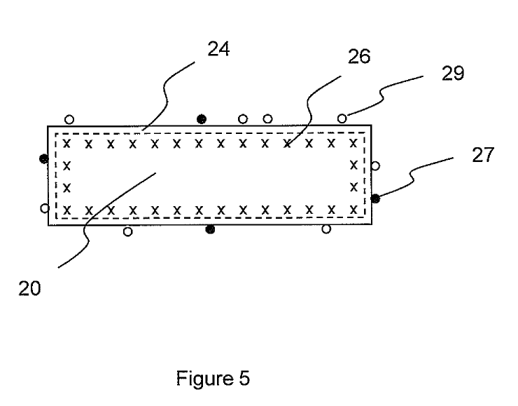

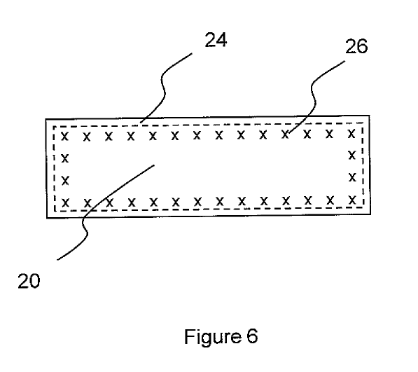

As illustrated in the cross-section view of FIGS. 5 and 6, the treated silicon body 20 may be cleaned with SC1 (NH₄OH:H₂O₂:H₂O=1:1:5) and SC2 (HCl:H₂O₂:H₂O=1:1:5) at the end of treatment, whether the treatment includes ion implantation or not, to remove contaminants 27 and particles 29 and to maintain a hydrophilic surface.

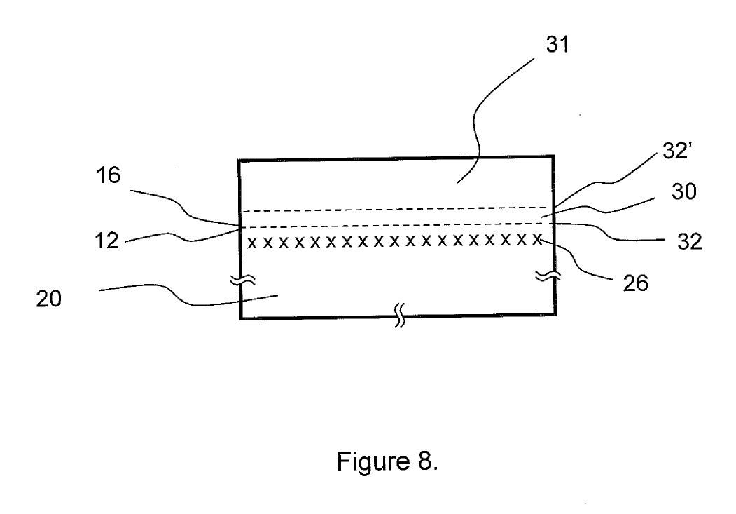

In another embodiment of the invention, the ion implanting is performed prior to the nitridation or oxidation, rather than after as in FIGS. 4 and 5. As illustrated in the cross-sectional view of FIG. 7, ion implantation into the silicon body 20 produces the high-stress regions 26 near or buried beneath the surface of the silicon body 20. The ion implantation may be performed prior to the hydrogen cleaning of FIG. 8 so that a native oxide layer 21 may be present during implantation. After the native oxide stripping, the surface is nitrided or oxidized to produce an amorphous layer 30 at low temperature, below the deposition temperature of SiN, with either nitrogen or oxygen plasma, as illustrated in the cross-sectional view of FIG. 8. When a surface region of the silicon body 12 is converted to silicon nitride or other silicon compound such as silicon oxide to form a tensile silicon nitride film 16 or other composition thereof, defects and interface states getter to the regions 26 of high stress, and the layer 30 forms an indistinct interface 32 with the silicon body 20. During the relatively high temperature LPCVD deposition of SiN 31 during IC fabrication, typically performed at about 760° C., defects or inclusions or silicon atoms or nitrogen atoms in the multiple SiN films 31 tend to migrate or move towards the high-energy regions 26 to reduce the overall free energy, thereby providing stronger adhesion for the after layers than does untreated polysilicon. Interfacial atoms in the polycrystalline silicon body 20, the atoms of the layer 30 and the atoms of the initially deposited film of the film 31 tend to migrate to the matrix to lower its high energy state, thereby removing the interfaces 32 and 32′ and forms the melded layer or region. The migration of materials from the production films can change the stress of the deposited film, even changing it from tensile to compressive by forming an inter-mixed layer or region with the silicon body 20. It is believed that the silicon nitride forms as an amorphous layer overlying the polycrystalline silicon and linking the crystallites.

When the nitride or oxide conversion is performed after the ion implantation, the conversion process should be performed at a relatively low temperature to prevent the high-energy states 26 from being annealed independently of incorporating the nitrogen or oxygen or other defects and grain boundaries. The nitridation or oxidation can be performed in a plasma process involving excited precursor molecules, such as ionized atoms or radicals. Energetic electrons can dissociate precursor molecules and create large quantities of free radicals. For nitridation, the precursor molecules may be nitrogen-containing gases, such nitrogen gas (N₂), ammonia (NH₃), or hydrazine (NH₂-NH₂). For oxidation, the precursor molecules may be oxygen-containing gases or vapors such as oxygen (O₂), water vapor (H₂O), hydrogen peroxide (H₂O₂), nitrous oxide (N₂O), or ozone (O₃). Otherwise unexcited ozone alone or in combination with hydrogen (H₂) is an effective low-temperature oxidizer. The plasma may be created in situ or remotely in a plasma chamber producing a plasma through an electric discharge using DC, RF, or microwave power. Alternatively, laser UV radiation effectively cracks the chemical bonds of precursor molecules and creates radicals.

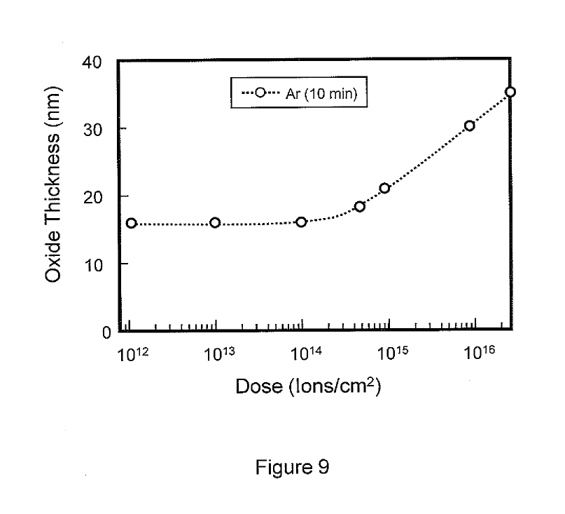

The high-energy states created by the ion implantation have been shown to be effective in a subsequent oxidation process. Plasma immersion ion implantation (PIII), to be described below, implanted different dose of argon ions into a series of silicon chips. The implanted chips were all subjected to the same set of oxidation conditions, and the thickness of the layers of silicon oxide was then measured. The results, shown in the graph of FIG. 9, demonstrate that at argon ion doses of 10¹⁴/cm² and below, the argon implant had little effect. However, at higher doses of 5×10¹⁴/cm² and greater, the oxide thickness begins to increase so that the implantation enhances the oxidation rate and evidently getters oxygen atoms from the surface oxide layer to the implanted region of high stress. At higher doses, the enhancement is proportional to dose.

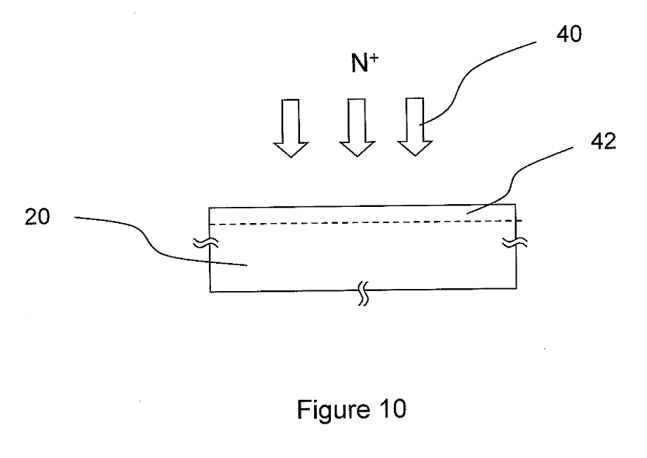

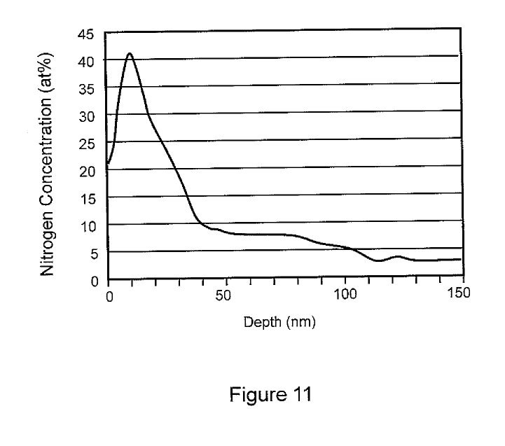

In another aspect of the invention, the ion implantation and nitridation or oxidation can be combined in a single process, illustrated in the cross-sectional view of FIG. 10, in which a beam 40 of energetic nitrogen ions (for nitridation) is directed to the silicon body 20 and forms a nitrided surface layer 42 in which the nitrogen is supplied by the ion beam 40. PIII of nitrogen was applied to both planar silicon pieces and to a silicon tower leg not being otherwise nitrided. The nitrogen atomic fractions as a function of depth were then measured. The results shown in the graph of FIG. 11 demonstrate that the incorporation of nitrogen was successful. The highest concentrations at depths of about 10 nm were in the range of 35 to 40 at % and significant nitrogen penetrated to 40 nm. It is possible to combine the nitrogen implant with the implanting of high-energy noble gases such as argon to further amorphize the silicon and provide further high-energy sites.

A similar process can be used to implant oxygen to convert the silicon surface to silicon oxide. Also, a similar process can be used to implant carbon to convert the silicon surface to silicon carbide.

Argon and other noble gases or silicon atoms can be implanted into an otherwise untreated surface of polysilicon to disorder a surface layer to the extent that it can be considered to be amorphous or to introduce the high-energy states which are effective at Bettering the production films and binding them to the furnaceware. Amorphous silicon is considered to be an effective passivation and barrier layer and to prevent the nucleation of grain boundaries of production layers thereafter deposited on the amorphous silicon layer. For amorphorization, the implantation should include low-energy components to assure that the near-surface layer is adequately disordered. For creation of high-energy states creating gettering states, the implant may be primarily deeper. If either silicon or a noble gas is implanted, no silicon compound is formed, but the silicon surface is disordered or high-energy states are created.

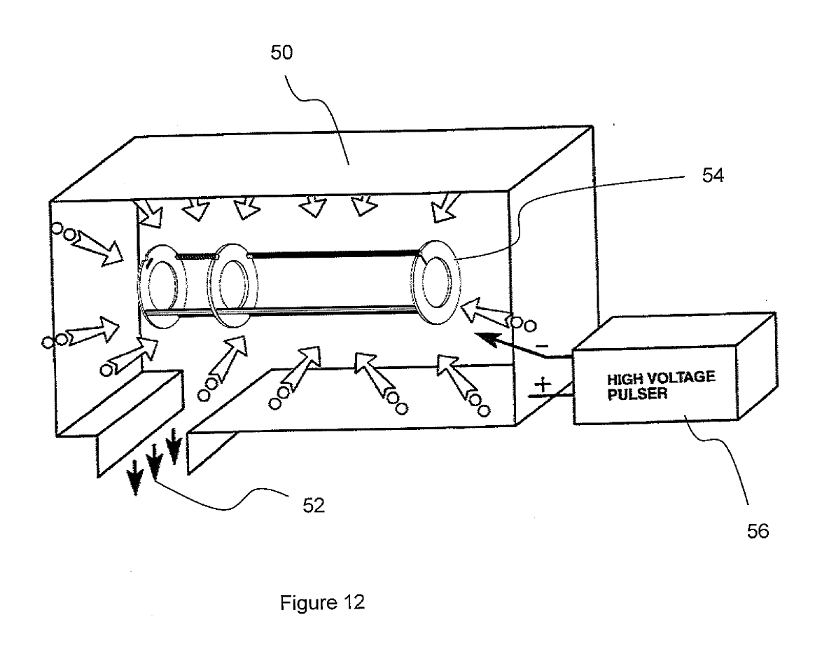

The ion implantation may be performed with plasma immersion ion implantation (PIII), as described by Mantese et al. in MRS Bulletin, vol. 21, no. 8, page 52 (1996) and as developed by Southwest Research Institute of San Antonio, Tex. A commercial version has been available from Silicon Genesis, Corporation of Campbell, Calif. As schematically illustrated in FIG. 12, PIII may be performed in a conductive vacuum chamber 50 which is vacuum pumped through a port 52 and is supplied with an implantation gas. A workpiece 54, which may be relatively large, is supported between and away from the walls of the vacuum chamber 50. A high-voltage power source 56, preferably a puller, is connected between the vacuum chamber 50 and the workpiece 54 to negatively bias the workpiece 54 with respect to the vacuum chamber 50. The voltage pulse ionizes the implantation gas into a plasma and forms a three-dimensional plasma sheath adjacent and around even a complexly shaped workpiece. The negatively biased workpiece 54 attracts the positively charged plasma ions across the sheath to the workpiece 54 at an energy determined by the voltage across the sheath. As a result, the applied voltage determines the energy at which the ions strike the workpiece 54 and hence the depth of their implantation. PIII is typically performed at low pressure of the ambient implantation gas in the sub-torr to millitorr range and at temperatures of typically less than 200° C. For very complexly and finely shaped parts, it may be necessary to rotate the part during implantation. Other types of ion implanters may be used, such as the conventional ion implantation guns producing a well defined and directed silicon beam.

Placing the silicon surface to be treated in the path of the accelerated ions causes the ions to be implanted into that silicon surface, even if the silicon part is itself not conductive, as would be the case with highly resistive virgin polysilicon. The resistive silicon part may be placed on a conductive electrode, which to maintain purity is preferably graphite rather than a metal so that any contaminants form relatively harmless silicon carbide. Alternatively, an electrode table of doped silicon or polysilicon may be of sufficient purity to produce no appreciable contamination. Alternatively, the polysilicon workpiece may be sufficiently doped to act as an electrode. Any contamination during implantation needs to be afterwards removed, preferably without removing significant amounts of silicon nitride. Alternatively, the silicon part may be suspected close to the electrode, thus resulting in simultaneous implantation of all surfaces while maintaining acceleration sufficient to result in implantation. If simultaneous implantation of all surfaces is not possible, the part may be rotated to expose all sides to the accelerated ions.

The ion implantation to increase residual stress or induce a high-energy state after the surface has been oxidized may be performed as described above with implanted C, Si, Ne, Ar, Kr, or Xe as well as with implanted oxygen from oxygen gas (O₂). Again, any contaminants should be cleaned from the surface.

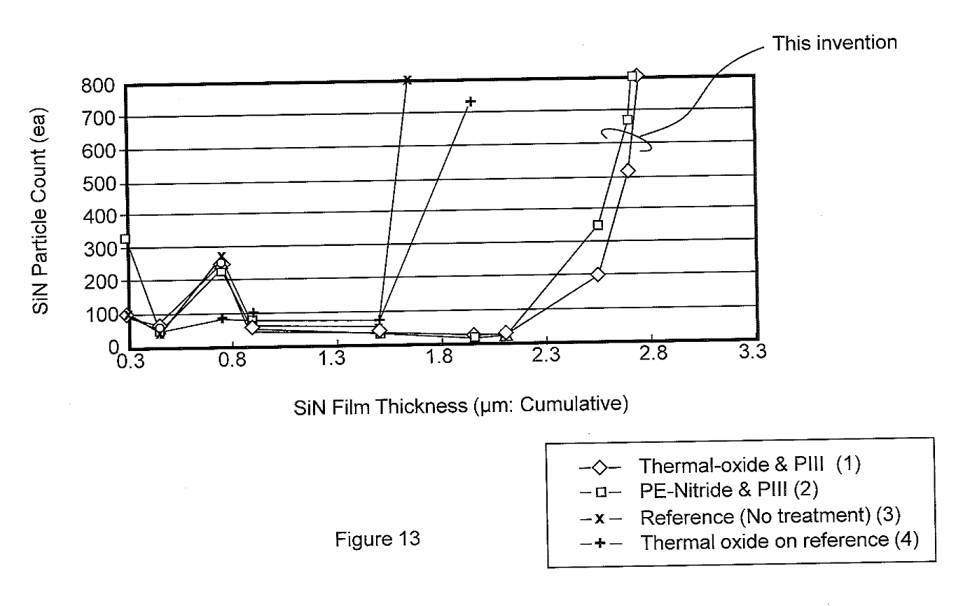

PIII of Argon was applied to both planar silicon pieces and to a silicon tower which were 1) thermally oxidized and, 2) plasma-enhanced nitrided before the PIII process. FIG. 13 shows that both of PIII processed silicon pieces and silicon tower have longer longevity on LPCVD-SiN application, showing the no failure of the film particle up to 2.5 μm, almost two (2) times longer than that of non-PIII silicon parts (as a reference 3) and thermal oxide on silicon parts 4.

Although the invention has been developed for furnaceware for processing silicon integrated circuit wafers, it may be applied to other polysilicon surfaces exposed to workpieces or media requiring high purity and very low contamination. The invention may also be applied to other materials for similar uses, such as single crystal silicon, silicon carbide and other ceramics.

What is claimed is:

1. A method of pre-treating a part to be used in a substrate or medium processing chamber, comprising:
oxidizing or nitriding the part to form an amorphous silicon nitride or silicon oxide layer on the part,
implanting an inert gas ion or an ion having a covalent radius equal to or less than that of silicon into the part.

2. The method of claim 1, wherein the implanting is performed by plasma immersion ion implantation, preferably performed with ions of greater than 1 keV implanting a dose of greater than 10¹⁴ atoms/cm².

3. The method of claim 2, wherein the implanting is performed before the oxidizing or nitriding.

4. The method of claim 2, wherein the implanting is performed after the oxidizing or nitriding.

5. The method of claim 2, wherein the implanting and oxidizing or nitriding are simultaneously performed.

6. The method of claim 2, wherein the part is furnaceware for thermally processing silicon wafers including towers, pedestals, injectors, liners and dummy and baffle wafers.

7. A method of pre-treating a part to be used in a substrate or medium processing chamber, comprising implanting carbon, nitrogen or oxygen into a surface region of the part to form respectively a silicon carbide, silicon nitride, or silicon oxide region.

8. A method of pre-treating a part to be used in a substrate or medium processing chamber, comprising implanting silicon or a noble gas heavier than helium into a surface region of the part to form a disordered surface region and/or regions of high energy.

9. The method of claim 8, wherein the implanting is performed by plasma immersion ion implantation.

10. The polysilicon product of any of claims 1 through 9.

11. A part in a processing chamber including an amorphous silicon nitride, silicon oxide, or silicon carbide layer covalently bonded with the underlying silicon or polysilicon and masking the polycrystallite structure of the polysilicon part.

12. The part of claim 11, further comprising regions of high energy underlying the silicon nitride, silicon oxide or silicon carbide layer.

13. A part in a processing chamber including an amorphous surface layer

14. The part of any of claims 10 through 13, which is a wafer support tower, tower pedestal, an oven liner, or a dummy or baffle wafer.
